(19) United States
(12) Patent Application Publication
(10) Pub. No.: US 2025/0046566 A1
(43) Pub. Date: Feb. 6, 2025

(54) Optical Apparatus and Charged Particle Beam Apparatus

(71) Applicant: Hitachi High-Tech Corporation, Tokyo (JP)

(72) Inventors: Masao YAMAMOTO, Tokyo (JP); Yuko OTANI, Tokyo (JP)

(21) Appl. No.: 18/787,676

(22) Filed: Jul. 29, 2024

(30) Foreign Application Priority Data
Aug. 4, 2023 (JP) 2023-127538

(51) Int. Cl. H01J 37/16; H01J 37/22

(52) U.S. Cl. CPC H01J 37/16; H01J 37/226; H01J 2237/006; H01J 2237/166; H01J 2237/188; H01J 2237/2445

(57) ABSTRACT

[Problem]

A technique capable of preventing gas containing a contaminant from flowing into a container and preventing inert gas flowing out of the container is provided.

[Solution]

An optical apparatus 100 includes a light irradiation device 1 capable of emitting light 3, a plurality of container components 13, 21, and 31, a gas supply port 22, and a gas suction port 32. A purge space 20 to which inert gas is supplied, a gas suction space 30 from which gas present is suctioned, and a space outside apparatus 80 are separated from each other by the plurality of container components 13, 21, and 31. The purge space 20 is used as the optical path of the light 3. An optical element 4b is disposed in the purge space 20. By supplying inert gas from a gas supply port 22 into the purge space 20 and suctioning gas present in the gas suction space 30 from the gas suction port 32, atmospheric pressure in the gas suction space 30 can be controlled to be lower than atmospheric pressure in the purge space 20 and atmospheric pressure in the space outside apparatus 80.

### TECHNICAL FIELD

The present invention relates to an optical apparatus and a charged particle beam apparatus.

### BACKGROUND ART

In a process of manufacturing a semiconductor device, foreign matter or a pattern defect may occur on a wafer that is a semiconductor substrate. The pattern defect is a short circuit defect, a disconnection defect, or the like.

Hereinafter, such foreign matter or such a pattern defect is merely referred to as a “defect”. These defects occur for various reasons during the manufacturing process. Therefore, it is important to detect a defect that occurs during the manufacturing process at an early stage, locate the source of the defect, and prevent a decrease in yield for mass production of semiconductor devices.

As a method of identifying the source of the defect, a method of identifying positional coordinates of the defect by an optical defect inspection apparatus, and observing the defect in detail based on information of the coordinates to estimate the source of the defect using a charged particle beam apparatus such as a scanning electron microscope (SEM).

The optical defect inspection apparatus uses a method of identifying the positional coordinates of the defect by emitting laser light onto the wafer and detecting light that has hit the defect and scattered from the defect. In addition, there is a discrepancy between the coordinate system of the optical defect inspection apparatus and the coordinate system of the SEM. To correct the discrepancy, a method of improving the success rate of defect supplementation by the SEM by reinspecting the defect or correcting the coordinate information of the defect by an optical microscope included in the SEM is used. For example, Patent Literature 1 discloses a defect observation apparatus including an optical microscope and an electronic microscope.

With the miniaturization of semiconductor devices, it has become necessary to detect and identify the source of an even finer defect. Since the defect detection sensitivities of the optical defect inspection apparatus and the optical microscope included in the SEM are improved as the wavelength of laser light is shorter. Therefore, the wavelength of laser light used to detect defects are becoming shorter.

Meanwhile, deep ultraviolet light with a wavelength shorter than 300 nm causes pollution sources such as oxygen and organic gas on an optical path to react, and causes contamination on a surface of an optical element. The accumulation of contamination causes a reduction in the performance of the optical element, such as a reduction in transmittance and reflectance. This is a problem when deep ultraviolet light is used.

Patent Literature 2 discloses a technique for using a photocatalyst to decompose a contaminant that clouds an optical element in an exposure apparatus. Patent Literature 3 discloses a system that reduces contamination by gas purge. It discloses a technique for preventing a contaminant from entering a vacuum area by injecting purge gas in a direction opposite to the vacuum area in a system in which an optical axis passes through a gas purge area and the vacuum area.

As general measures against contamination, there is a method (inert gas purge method) in which filtered clean inert gas is introduced into a container including a laser beam path to discharge a contamination source and oxygen. The inert gas is, for example, nitrogen or noble gas such as argon.

### CITATION LIST

### Patent Literature

Patent Literature 1: Japanese Unexamined Patent Application Publication No. 2007-235023
Patent Literature 2: Japanese Unexamined Patent Application Publication No. 2005-72076
Patent Literature 3: U.S. Patent Application Publication No. 2022/0382046

### SUMMARY OF INVENTION

### Technical Problem

To discharge a contaminant and oxygen from the optical path and prevent them from entering again, it is necessary to fill the container with clean inert gas. Meanwhile, when the inert gas flows out of the container, there is a possibility that the oxygen concentration in a space around the container may decrease.

In the case of an SEM apparatus including an optical microscope, it is installed in a cover of the SEM apparatus, there is a possibility that a decrease in oxygen concentration in the SEM apparatus may pose a problem when an operator performs maintenance work.

It is conceivable to avoid such a problem by making a container be a hermetically closed container. To achieve this, it is necessary to manufacture the container by a method such as integral molding or machining, and eliminate parts where gas flows into and out of the container. However, such a method leads to an increase in the manufacturing cost.

In a case where a deep ultraviolet light irradiation device representative of a laser head, or an optical element provided with an electric part is included in a container including an optical path targeted for purge, a structure for drawing out a power supply for it and a control cable to the outside of the optical path container is required. Therefore, it is difficult to make a completely hermetically closed container space.

Similarly, even in a case where a portion of a deep ultraviolet light irradiation device including an exit port is included in a container, the container is no longer integrally molded and sealability decreases.

A main object of the present application is to provide a technique that can prevent gas containing a contaminant from entering a container and prevent inert gas from flowing out of the container even in a case where the container is not completely hermetically closed.

Other objects and novel features will become apparent from the description herein and the accompanying drawings.

### Solution to Problem

An optical apparatus according to an aspect includes a light irradiation device capable of emitting light, a plurality of container components, a first gas supply port, a first gas suction port, and a first optical element. A first space to which inert gas is supplied, a second space from which gas present is suctioned, and a third space where is a space present outside the plurality of container components are separated from each other from the plurality of container components, the first gas supply port reaches the first space, the first gas suction port reaches the second space, the first space is used as an optical path of the light, the first optical element is disposed in the first space, and atmospheric pressure in the second space can be controlled to be lower than atmospheric pressure in the first space and atmospheric pressure in the third space by supplying the inert gas from the first gas supply port into the first space, and suctioning the gas present in the second space from the first gas suction port.

### Advantageous Effects of Invention

According to the optical apparatus according to the aspect, it is possible to prevent gas containing a contaminant from flowing into a container and prevent inert gas from flowing out of the container.

### BRIEF DESCRIPTION OF DRAWINGS

FIG. 1 is a schematic diagram illustrating an optical apparatus according to a first embodiment.

FIG. 2 is a schematic diagram illustrating a portion of an optical apparatus according to Modification 1.

FIG. 3 is a schematic diagram illustrating a portion of an optical apparatus according to Modification 2.

FIG. 4 is a schematic diagram illustrating a portion of an optical apparatus according to Modification 3.

FIG. 5 is a schematic diagram illustrating an optical apparatus according to a second embodiment.

FIG. 6 is a schematic diagram illustrating an optical apparatus according to a third embodiment.

FIG. 7 is a perspective view illustrating a plurality of container components according to the third embodiment.

FIG. 8 is a perspective view illustrating a container component according to Modification 4.

FIG. 9 is a cross-sectional view illustrating the container component according to Modification 4.

FIG. 10 is a perspective view illustrating a container component according to Modification 5.

FIG. 11 is a cross-sectional view illustrating the container component according to Modification 5.

FIG. 12 is a schematic diagram illustrating an optical apparatus according to a fourth embodiment.

### DESCRIPTION OF EMBODIMENTS

Hereinafter, embodiments will be described in detail with reference to the drawings. In all the drawings for explaining the embodiments, members having the same functions are denoted by the same reference signs and redundant description is omitted. In the following embodiments, explanations of the same or similar parts are not repeated as a general rule unless they are particularly necessary.

X, Y, and Z directions described in the present application intersect each other or are perpendicular to each other. In the present application, the description will be made using the Z direction as a vertical direction of a structure.

### First Embodiment

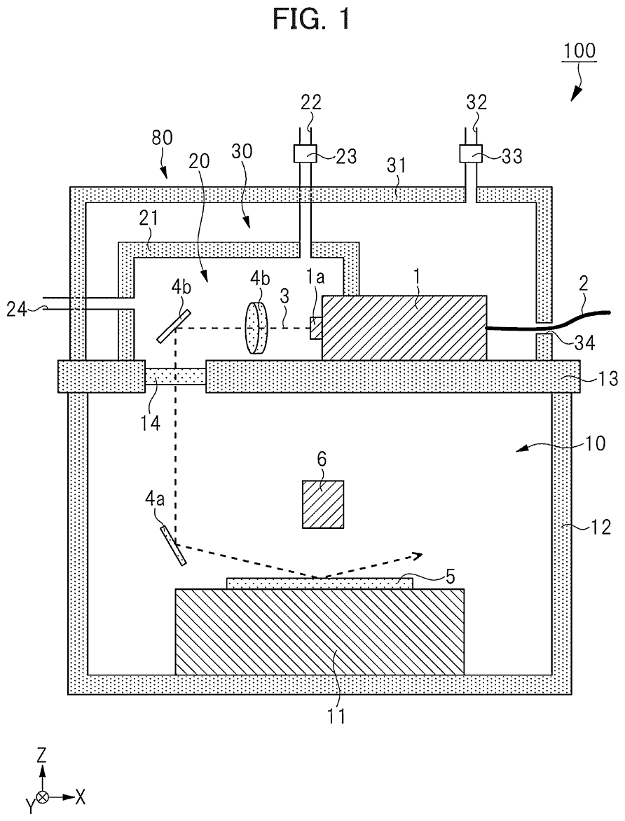

An optical apparatus 100 according to a first embodiment will be described below with reference to FIG. 1.

As illustrated in FIG. 1, the optical apparatus 100 mainly includes a light irradiation device 1, an optical element 4a, an optical element 4b, a light detector 6, a stage 11, a sample container component 12, a plurality of container components 13, 21, and 31, a gas supply port 22, gas supply adjustment equipment 23, an ejection port 24, a gas suction port 32, and gas suction adjustment equipment 33.

The light irradiation device 1 is mounted on a flat plate-shaped container component 13, includes a light source 1a, and is capable of emitting light 3 from the light source 1a. The light 3 is, for example, light with a wavelength of 300 nm or less, and is deep ultraviolet light. The sample container component 12 is joined to the container component 13 by using an O ring or the like. A space surrounded by the sample container component 12 and the container component 13 is a sample space 10 that is a hermetically closed space. A sealing window 14 through which the light 3 can pass is attached to a portion of the container component 13.

A purge space 20 to which inert gas is supplied, a gas suction space 30 from which gas present is suctioned, and a space outside apparatus 80 are separated from each other by the container components 13, 21, and 31. The space outside apparatus 80 is a space to which it is not desirable that inert gas flows out. Also, the space outside apparatus 80 is a space that is outside the sample container component 12 and the container components 13, 21, and 31 and surrounds the optical apparatus 100.

In the sample space 10, one or more optical elements 4a are disposed. In the purge space 20, one or more optical elements 4b are disposed. The optical elements 4a and 4b include, for example, an element for switching an optical path of the light 3 like a mirror, and an element for controlling the intensity, polarization, beam diameter, and the like of the light 3.

The stage 11 is disposed in the sample space 10, and a sample 5 can be placed on the stage 11. The sample 5 is, for example, a wafer including a semiconductor substrate, a semiconductor element, such as a transistor, formed on the semiconductor substrate, a plurality of wire lines formed on the semiconductor element, and the like.

The light detector 6 is disposed in the sample space 10 and can detect scattered light or fluorescence emitted from the sample 5. It is possible to identify positional coordinates of a defect of the sample 5 based on the result of the detection by the light detector 6.

The purge space 20 is used as the optical path of the light 3. The light 3 emitted from the light irradiation device 1 enters the sample space 10 from the purge space 20 and reaches the sample 5 while passing through the plurality of optical elements 4b and 4a. In order for the light 3 to enter the sample space 10 from the purge space 20, the light 3 passes through the sealing window 14. Thereafter, the light detector 6 is used to identify the positional coordinates of the defect.

The cover-shaped container component 21 can be bent and is formed of a thin metal plate and joined to the container component 13, for example. The purge space 20 is a space surrounded by the container component 13 and the container component 21. At least a portion of the light irradiation device 1 is covered with the container component 21 such that the light source 1a of the light irradiation device 1 is located in the purge space 20. Therefore, the purge space 20 in the first embodiment is a space surrounded by the light irradiation device 1, the container component 13, and the container component 21.

The gas supply port 22 is disposed in the container component 21 so as to reach the purge space 20. The gas supply adjustment equipment 23 is attached to the gas supply port 22. The gas supply adjustment equipment 23 is used to adjust the amount of inert gas to be supplied, and is, for example, a regulator. Although not illustrated, the gas supply port 22 is connected to gas supply equipment such as a pump provided outside the optical apparatus 100. Inert gas is supplied into the purge space 20 by the gas supply equipment. The inert gas is, for example, nitrogen or noble gas such as argon.

The purpose of supplying inert gas into the purge space 20 is not to fill the purge space 20 with inert gas but to continue gas inflow and gas outflow in order not to accumulate contaminants in the purge space 20. Therefore, inert gas is sequentially (continuously) supplied from the gas supply port 22 into the purge space 20.

Although a space between the sealing window 14 and the container component 13 is hermetically closed, for example, gas flows into and out of the purge space 20 between the container component 21 and the container component 13 and between the container component 21 and the light irradiation device 1. Therefore, in the first embodiment, the gas suction space 30 is disposed between the purge space 20 and the space outside apparatus 80 by the container component 31.

The cover-shaped container component 31, for example, can be bent and is formed of a thin metal plate and joined to the container component 13 so as to cover the container component 21. The gas suction space 30 is a space surrounded by the container component 13, the container component 21, and the container component 31. The gas suction port 32 is disposed in the container component 31 so as to reach the gas suction space 30. The gas suction adjustment equipment 33 for adjusting a suction force is attached to the gas supply port 32. Although not illustrated, the gas suction port 32 is connected to gas suction equipment such as a pump provided outside the optical apparatus 100. The gas suction equipment suctions gas present in the gas suction space 30 from the gas suction port 32. The suctioned gas is collected into a safe place by other means.

Gas may flow into and out of the gas suction space 30 between the container component 31 and the container component 13. A hole 34 for a cable is disposed in the container component 31 in order to draw out a cable 2 of the light irradiation device 1. Gas may flow into and out through the hole 34.

Thus, in a case where the defect of the sample 5 is to be detected, inert gas is supplied from the gas supply port 22 into the purge space 20, and gas preset in the gas suction space 30 is suctioned from the gas suction port 32. Therefore, atmospheric pressure in the gas suction place 30 can be suppressed to be lower than atmospheric pressure in the purge space 20 and atmospheric pressure in the space outside apparatus 80.

Therefore, even in a case where inert gas flows out of the purge space 20 into the gas suction space 30, the inert gas is suctioned into the gas suction port 32. In addition, it is possible to prevent gas from flowing out of the space outside apparatus 80 into the purge space 20 and prevent gas from flowing out of the gas suction space 30 into the space outside apparatus 80. That is, according to the first embodiment, even in a case where the container is not completely hermetically closed, it is possible to prevent other gas from flowing into the purge space 20 and prevent inert gas from flowing to the outside of the optical apparatus 100.

In addition, in a case where the sample 5 is placed on the stage 11, and the defect of the sample 5 is to be detected, the light 3 is emitted from the light irradiation device 1 in a state in which the atmospheric pressure in the gas suction space 30 is controlled to be lower than the atmospheric pressure in the purge space 20 and the atmospheric pressure in the space outside apparatus 80. The purge space 20 that serves as the optical path of the light 3 is filled with the inert gas. Therefore, in a case where the sample 5 is placed on the stage 11 and the defect of the sample 5 is to be detected, even when deep ultraviolet light is used, accumulation of contamination is suppressed. Therefore, it is possible to suppress a reduction in the performance of the optical element 4b and the light source 1a.

The ejection port 24 is disposed in the container component 21. The inert gas with which the purge space 20 is filled is naturally ejected from the ejection port 24 to the outside of the optical apparatus 100. The ejected inert gas is collected into a safe place by other means. However, in a case where the apparatus is designed such that all the inert gas supplied into the purge space 20 is ejected from the gas supply port 32 through the gas suction space 30, the ejection port 24 may not be provided.

In addition, the sample space 10 is kept in vacuum. Particularly, in a case where the optical apparatus 100 is a portion of a configuration included in a charged particle beam apparatus such as an SEM apparatus, the sample space 10 is shared with a process of observing an SEM image, and thus it is desirable that the sample space 10 is a vacuum. In a case where the sample space 10 is a vacuum, contaminants and oxygen are excluded, and there is no concern about contamination in the sample space 10. The light 3 passes through the sealing window 14 and enters the sample space 10 from the purge space 20. The sample space 10 can be purged by using inert gas. However, in this case, a mechanism that plays the same roles as those of the gas supply port 22 and the ejection port 24 may be installed in the sample container 12.

The charged particle beam apparatus includes, in the sample space 10, an electron beam lens barrel capable of emitting an electron beam. However, the state 11 on which the sample 5 is placed can be moved between a position where the light 3 reaches and a position to which the electron beam is emitted. Therefore, a process of observing an SEM image can be performed immediately after the defect detection by the optical apparatus 100 is ended.

### (Modification 1)

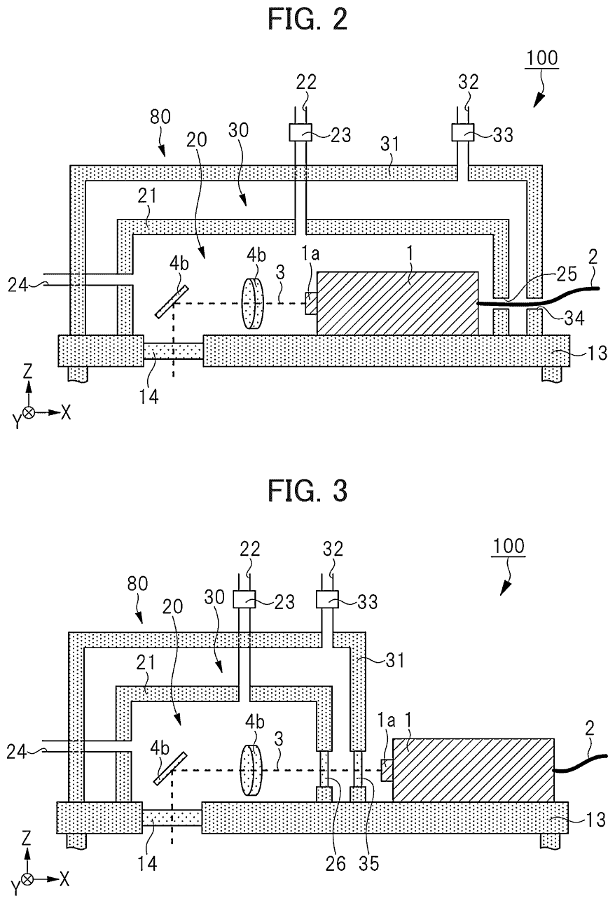

Modification 1 of the first embodiment will be described with reference to FIG. 2. In Modification 1, Modification 2, and Modification 3, a case where the position of the light irradiation device 1 is different from that described in the first embodiment is described. However, for simplification, the description will be made using the drawings in which a configuration that includes the sample space 10 and the like and is present below the container component 13 is omitted.

As illustrated in FIG. 2, in Modification 1, the entire light irradiation device 1 is covered with the container component 21 such that the light source 1a is located in the purge space 20. Therefore, a hole 25 for a cable is disposed in the container component 21 in order to draw out the cable 2. For example, the degree at which the purge space 20 is hermetically closed can be improved in a case where a space between the cable 2 and the hole 25 can be sealed by effective means.

### (Modification 2)

Modification 2 of the first embodiment will be described with reference to FIG. 3.

As illustrated in FIG. 3, in Modification 2, the entire light irradiation device 1 is disposed outside the container component 31 such that the light source 1a is located in the space outside apparatus 80. Therefore, a sealing window 26 through which the light 3 can pass is attached to a portion of the container component 21. A sealing window 35 through which the light 3 can pass is attached to a portion of the container component 31. The light 3 can enter the gas suction space 30 from the space outside apparatus 80 by passing through the sealing window 35 and can enter the purge space 20 from the gas suction space 30 by passing through the sealing window 26.

In Modification 2, since a space from the light source 1a to the outside of the sealing window 26 is not targeted for purge, there is a concern that contamination may adhere to the light irradiation device 1 and the sealing windows 26 and 35. However, since the light irradiation device 1 is not used for the constituent elements in the purge space 20, the degree at which the purge space 20 is hermetically closed can be increased and thus it is easy to reduce the possibility that contamination may adhere to the optical element 4b. In a case where the cost of cleaning or replacing the optical element 4b is higher than the cost of cleaning or replacing and the like each of the light source 1a, the sealing window 26, and the sealing window 35, it is possible to suppress an increase in the cost of the cleaning or the replacement. In addition, in a case where the light irradiation device 1 itself is replaced, the work for the replacement can be easily performed in Modification 2.

### (Modification 3)

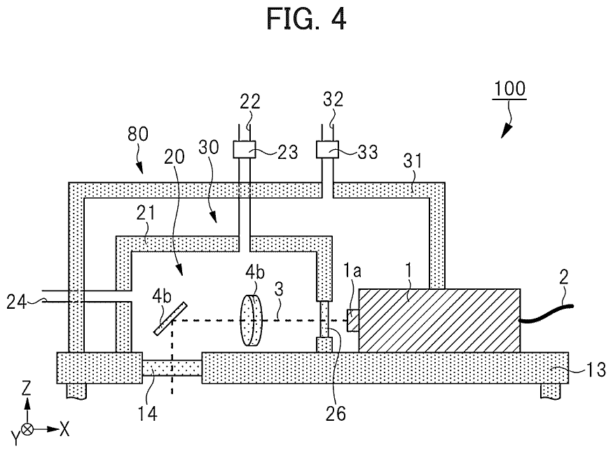

Modification 3 of the first embodiment will be described with reference to FIG. 4.

As illustrated in FIG. 4, in Modification 3, at least a portion of the light irradiation device 1 is covered with the container component 31 such that the light source 1a is located in the gas suction space 30. Therefore, a sealing window 26 through which the light 3 can pass is attached to a portion of the container component 21. The light 3 can enter the purge space 20 from the gas suction space 30 by passing through the sealing window 26.

As in Modification 2, in Modification 3, since the space from the light source 1a to the outside of the sealing window 26 is not targeted for purge, there is a concern that contamination may adhere to the light irradiation device 1, but the effect of the adhesion in Modification 3 is lower than the effect of the adhesion in Modification 2. In addition, since the light irradiation device 1 is not used for the constituent elements in the purge space 20, the degree at which the purge space 20 is hermetically closed can be increased and thus it is easy to reduce the possibility that contamination may adhere to the optical element 4.

### Second Embodiment

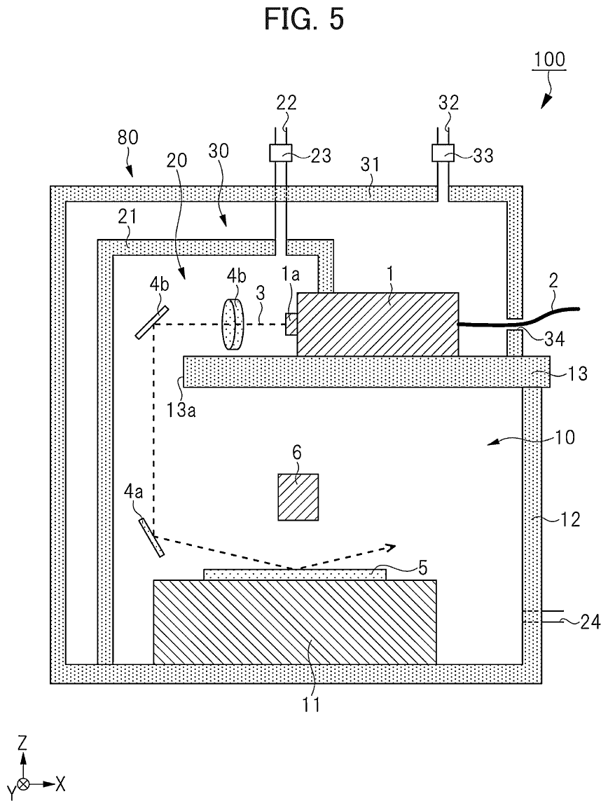

An optical apparatus 100 according to a second embodiment will be described with reference to FIG. 5. In the following description, differences from the first embodiment will be mainly described, and description of features that overlap with the first embodiment will be omitted.

In the first embodiment, a sample space 10 and a purge space 20 are separated from each other. In the second embodiment, an opening 13a is provided in a portion of a container component 13, and the sample space 10 and the purge space 20 are the same space. Therefore, in a case where a defect of a sample 5 is to be detected, the sample space 10 and the purge space 20 are filled with inert gas. Since an optical path of light 3 is filled with inert gas, accumulation of contamination is suppressed even when deep ultraviolet light is used.

The optical apparatus 100 according to the second embodiment is applied in a case where it is not necessary that the sample space 10 be a vacuum. Work for making the sample space 10 as a vacuum is not necessary, and the configuration of the apparatus will be simple.

The techniques disclosed in Modification 1, Modification 2, and Modification 3 can be applied to the second embodiment.

### Third Embodiment

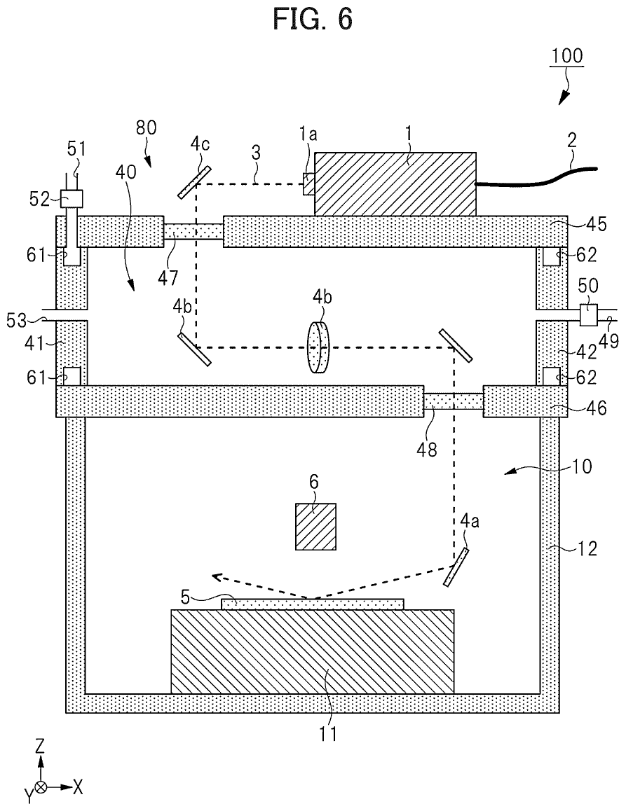

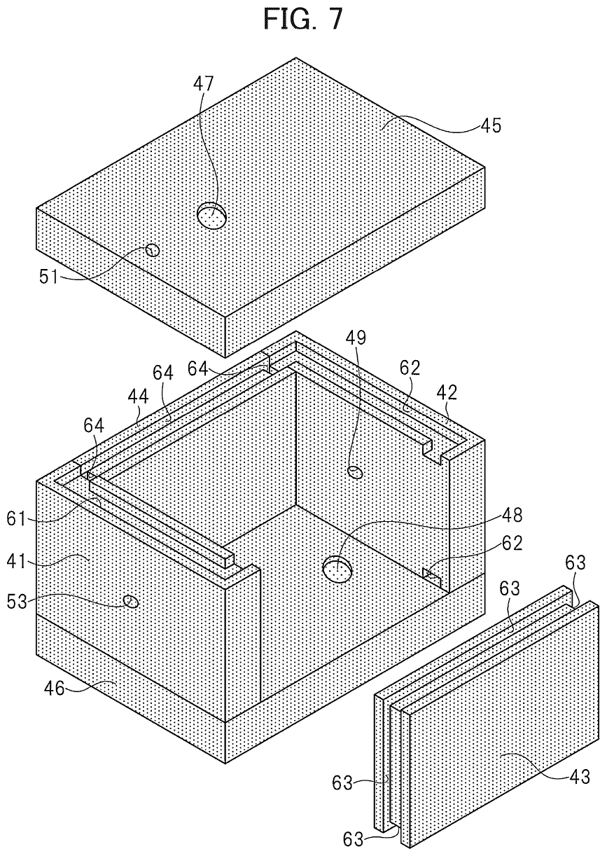

An optical apparatus 100 according to a third embodiment will be described below with reference to FIG. 6 and FIG. 7. In the following description, differences from the first embodiment will be mainly described, and description of features that overlap with the first embodiment will be omitted.

In the first embodiment, the purge space 20 and the gas suction space 30 are formed by using the container components of two layers, which are the container component 13 and the container component 21. In a third embodiment, a purge space and a gas suction space are formed by using a one-layer container component and a groove formed in the one-layer container component.

As illustrated in FIG. 6 and FIG. 7, an optical apparatus 100 according to the third embodiment includes a plurality of flat plate-shaped container components 41, 42, 43, 44, 45, and 46. The container component 45 and the container component 46 face each other, and each of the plurality of container components 41, 42, 43, and 44 is joined by means such as a screw. In addition, the plurality of container components 41, 42, 43, and 44 are partially joined to each other by means such as screws. That is, each of the container components 41, 42, 43, 44, 45, and 46 is joined to the container components other than the container component which each of the container components faces.

The shape of the container component 45 forming an upper wall and the shape of the container component 46 forming a lower wall are square shapes but may be other polygonal shapes. The number of the plurality of container components 41, 42, 43, and 44 forming side walls is not limited to 4 and may be 5 or more.

In the third embodiment, the purge space 40, the gas suction space, and a space outside apparatus 80 are separated from each other by the container components 41, 42, 43, 44, 45, and 46. A space surrounded by the container components 41, 42, 43, 44, 45, and 46 forms the purge space 40 to which inert gas is supplied. One or more optical elements 4b are disposed in the purge space 40.

The light irradiation device 1 is disposed on the container component 45. One or more optical elements 4c are disposed in the space outside apparatus 80. The optical element 4c is similar to the optical elements 4a and 4b. The container component 46 facing the container component 45 is joined to a sample container component 12 by using an O ring or the like. A sealing window 47 is attached to a portion of the container component 45, and a sealing window 48 is attached to a portion of the container component 46.

The purge space 40 is used as an optical path of light 3. The light 3 emitted from the light irradiation device 1 enters the purge space 40 from the space outside apparatus 80, enters the sample space 10 from the purge space 40, and reaches the sample 5 while passing through the plurality of optical elements 4c, 4b, and 4a. To enter the purge space 40 from the space outside apparatus 80, the light 3 passes through the sealing window 47. In addition, to enter the sample space 10 from the purge space 40, the light 3 passes through the sealing window 48. Thereafter, the light detector 6 is used to identify the positional coordinates of the defect.

Grooves 61, 62, 63, and 64 are formed along a joint surface of the container component 45 and the container components 41, 42, 43, and 44, a joint surface of the container component 46 and the container components 41, 42, 43, and 44, and a joint surface of the container components 41, 42, 43, and 44 one another. That is, the grooves 61, 62, 63, and 64 are formed in the container components 41, 42, 43, and 44, respectively. The grooves 63 and 64 are formed also in the vertical direction (Z direction). Therefore, in a case where the container components 41, 42, 43, 44, 45, and 46 are joined as a single container, the grooves 61, 62, 63, and 64 communicate with each other as a single groove. The grooves 61, 62, 63, and 64 function as a gas suction space corresponding to the gas suction space 30 described in the first embodiment.

The container components 41, 42, 43, 44, 45, and 46 are, for example, formed of thick metal plates such as aluminum or copper. The grooves 61, 62, 63, and 64 are formed in the container components 41, 42, 43, and 44 by cutting processing.

A gas supply port 49 is disposed in the container component 42 so as to reach the purge space 40. Gas supply adjustment equipment 50 is attached to the gas supply port 49. A gas suction port 51 is disposed in the container component 45 so as to reach the groove 61. Gas suction adjustment equipment 52 is attached to the gas suction port 51. An ejection port 53 is disposed in the container component 41.

The gas supply adjustment equipment 50 and the gas suction adjustment equipment 52 have similar functions to those of the gas supply adjustment equipment 23 and the gas suction adjustment equipment 33 described in the first embodiment, respectively. Although not illustrated, the gas supply port 49 is connected to gas supply equipment such as a pump provided outside the optical apparatus 100. The gas supply equipment supplies inert gas into the purge space 40. In addition, the gas suction port 51 is connected to gas suction equipment such as a pump provided outside the optical apparatus 100. The gas suction equipment suctions gas present in the gas suction space from the gas suction port.

In the third embodiment, in a case where the container components 41, 42, 43, 44, 45, and 46 are joined as a single container, gas may flow into and out of the container through a joint surface of the container components. However, the gas suction space formed by the grooves 61, 62, 63, and 64 is disposed between the purge space 40 and the space outside apparatus 80.

Therefore, in a case where the defect of the sample 5 is to be detected, inert gas is supplied from the gas supply port 49 into the purge space 40, gas present in the gas suction space (grooves 61, 62, 63, and 64) is suctioned from the gas suction port 51. Therefore, atmospheric pressure in the gas suction space can be controlled to be lower than atmospheric pressure in the purge space 40 and atmospheric pressure in the space outside apparatus 80.

In a case where the sample 5 is placed on the stage 11, and the defect of the sample 5 is to be detected, the light 3 is emitted from the light irradiation device 1 in a state in which the atmospheric pressure in the gas suction space 30 is controlled to be lower than the atmospheric pressure in the purge space 40 and the atmospheric pressure in the space outside apparatus 80.

As in the first embodiment, in the third embodiment, even in a case where the container is not completely hermetically closed, it is possible to prevent other gas from flowing into the purge space 40 and prevent the inert gas from flowing out of the optical apparatus 100. The purge space 40 serving as the optical path of the light 3 is filled with the inert gas. Therefore, even in a case where deep ultraviolet light is used, accumulation of contamination is suppressed. Therefore, it is possible to suppress a decrease in the performance of the optical element 4b.

In the structure using the grooves 61, 62, 63, and 64 in the third embodiment, it is not necessary to add a new component in order to provide the gas suction space, and thus there is an advantage that the number of components can be reduced, compared with the first embodiment.

The case where the grooves 61, 62, 63, and 64 are formed in the container components 41, 42, 43, and 44, respectively, is described as an example. However, it suffices for the grooves to be formed along the joint surfaces of the container components. For example, grooves may be formed in the container components 45 and 46.

In addition, the gas supply port 49, the gas suction port 51, and the ejection port 53 may not limited to being disposed in the container component 42, the container component 45, and the container component 41, respectively, and may be disposed in other container components. That is, each of the gas supply port 49, the gas suction port 51, and the ejection port 53 is disposed in any one of the container components 41, 42, 43, 44, 45, and 46. In addition, a plurality of gas suction ports 51 may be disposed in consideration of the balance of the atmospheric pressure.

### (Modification 4)

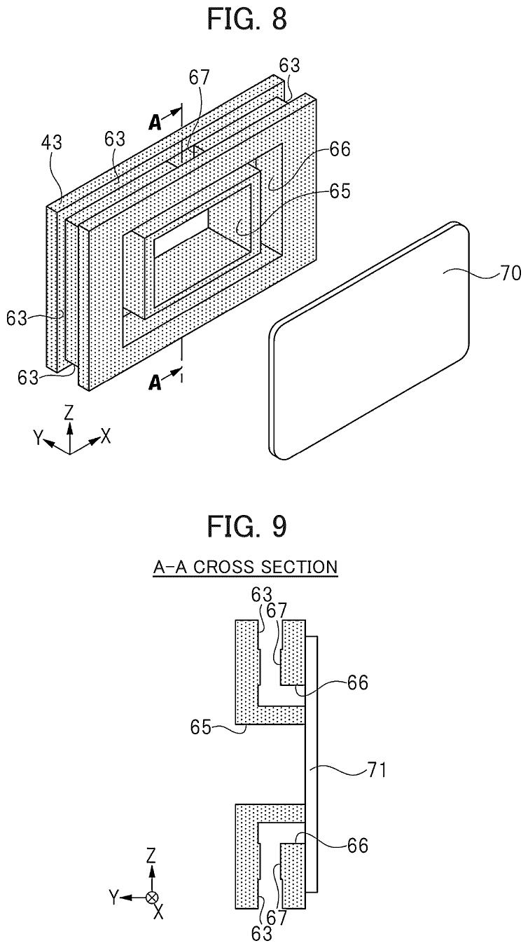

Modification 4 of the third embodiment will be described below with reference to FIG. 8 and FIG. 9. FIG. 9 is a cross-sectional view taken along line A-A illustrated in FIG. 8.

As illustrated in FIG. 8 and FIG. 9, in Modification 4, a through-hole 65 opening the purge space 40 and the space outside apparatus 80 is formed in the container component 43. In other words, the container component 43 includes an inner wall surface on the purge space 40 side and an outer wall surface on the space outside apparatus 80 side. The through-hole 65 is formed so as to penetrate the outer wall surface and the inner wall surface of the container component 43.

For example, work for adjustment or maintenance and the like of the plurality of optical elements 4b may be necessary, and access to the inside of the purge space 40 may be necessary. In this case, in a case where a structure that allows the inside of the purge space 40 to be accessed without disassembly of the container components 41, 42, 43, 44, 45, and 46, the above-described work can be easily performed. The through-hole 65 is provided to play the role.

A sealing component 70 is joined to the container component 43 by means such as a screw so as to cover the through-hole 65. However, since a joint surface of the container component 43 and the sealing component 70 is not hermetically closed, inflow and outflow of gas may occur. As a method of sealing the through-hole 65, a method of fitting an O ring is conceivable. However, in a case where it is assumed that the use of the O ring is difficult, such as a case where there is a concern about degradation of the O ring, or a case where the O ring itself may be a source of contamination, Modification 4 is useful.

A recessed portion 66 is formed in the container component 43 around the through-hole 65. The recessed portion 66 is formed so as to reach a predetermined depth from the outer wall surface in a direction from the outer wall surface to the inner wall surface of the container component 43. A hole 67 is formed in a bottom of the groove 63 of the container component 43 such that the groove 63 and the recessed portion 66 communicate with each other. The sealing component 70 is provided so as to also cover the recessed portion 66.

Since the groove 63 and the recessed portion 66 communicate with each other via the hole 67, the inside of the recessed portion 66 serves as a part of the gas suction space. Therefore, even when inert gas flows out around the through-hole 65, the inert gas is suctioned from the gas suction port 51.

As described above, according to Modification 4, it is possible to easily access the inside of the purge space 40 and prevent inert gas from flowing out.

A container component in which the through-hole 65, the recessed portion 66, and the hole 67 are formed is not limited to the container component 43, and may be the container component 41, 42, or 44.

### (Modification 5)

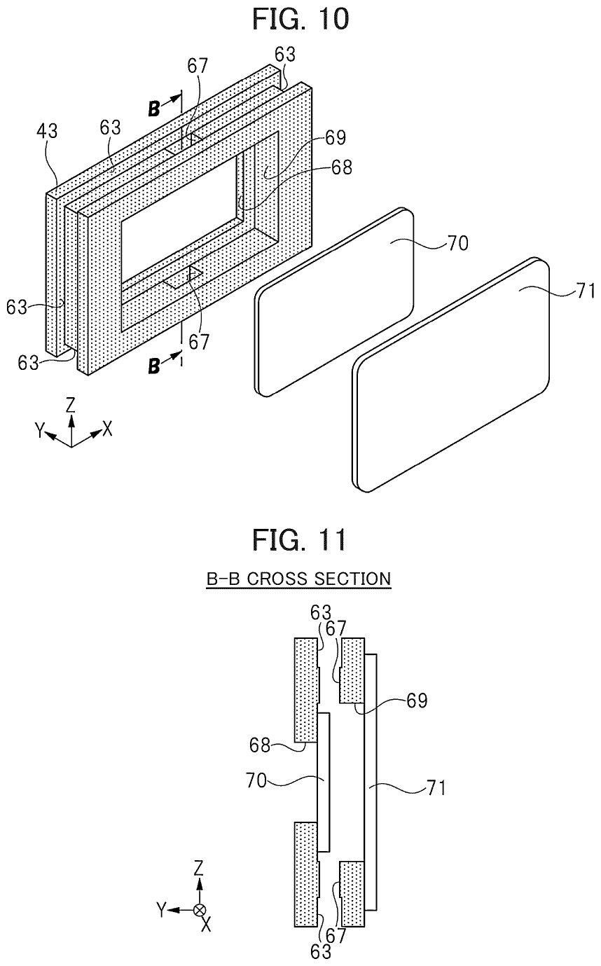

Modification 5 of the third embodiment will be described with reference to FIG. 10 and FIG. 11. FIG. 11 is a cross-sectional view taken along line B-B illustrated in FIG. 10.

As in Modification 4, in Modification 5, a structure designed to easily access the inside of the purge space 40 is provided.

A recessed portion 69 is formed in the container component 43. The recessed portion 69 is formed so as to reach a predetermined depth from the outer wall surface in a direction from the outer wall surface to the inner wall surface of the container component 43. A through-hole 68 opening the purge space 40 and the space outside apparatus 80 is formed in a bottom of the recessed portion 69. The through-hole 68 is formed so as to penetrate the outer wall surface of the container component 43 and the bottom of the recessed portion 69.

A hole 67 is formed in the bottom of the groove 63 of the container component 43 such that the groove 63 and the recessed portion 69 communicate with each other. The sealing component 70 is joined to the bottom of the recessed portion 69 by means such as a screw so as to cover the through-hole 68. A sealing component 71 is joined to the container component 43 by means such as a screw so as to cover the recessed portion 69.

Since the groove 63 and the recessed portion 69 communicate with each other via the hole 67, the inside of the recessed portion 69 serves as a part of the gas suction space. That is, a space between the sealing component 70 and the sealing component 71 serves as a part of the gas suction space. Therefore, even when inert gas flows out around the through-hole 68, the inert gas is suctioned from the gas suction port 51.

As described above, even in Modification 5, it is possible to easily access the inside of the purge space 40 and prevent inert gas from flowing out.

A container component in which the through-hole 68, the recessed portion 69, and the hole 67 are formed is not limited to the container component 43, and may be the container component 41, 42, or 44.

### Fourth Embodiment

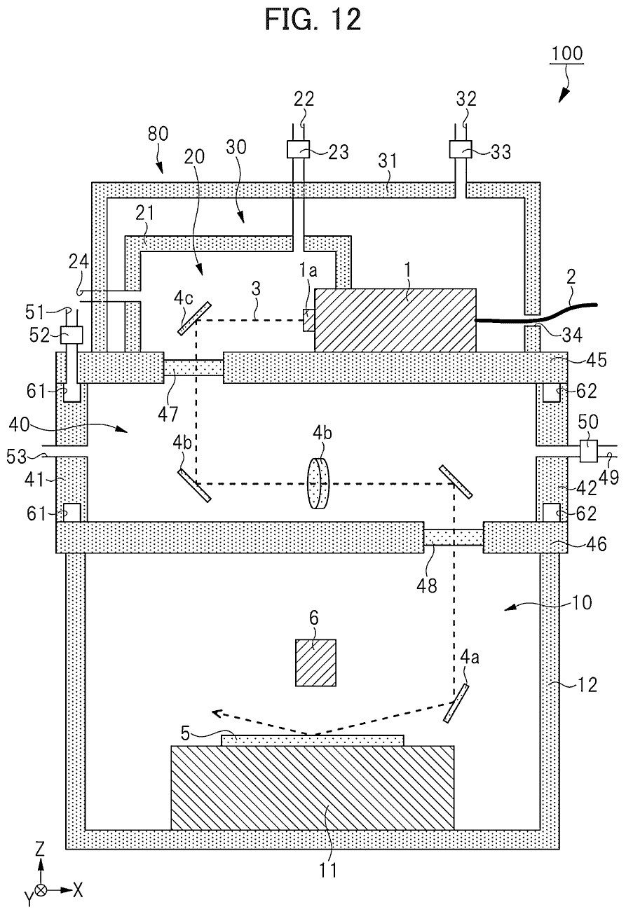

An optical apparatus 100 according to a fourth embodiment will be described with reference to FIG. 12. In the following description, differences from the third embodiment will be mainly described below, and description of features that overlap with the third embodiment will be omitted.

As illustrated in FIG. 12, in the fourth embodiment, container components 41, 42, 43, 44, 45, and 46 and the like that are similar to those described in the third embodiment are used, and the container components 21 and 31 and the like described in the first embodiment are used. The light irradiation device 1 is disposed on the container component 45. The container components 21 and 31 are joined to the container component 45, respectively. The optical element 4c disposed in the space outside apparatus 80 in the third embodiment is disposed in a purge space 20.

In a case where the defect of the sample 5 is to be detected, inert gas is supplied from a gas supply port 22 into the purge space 20, and gas present in a gas suction space 30 is suctioned from a gas suction port 32. At the same time, inert gas is supplied from a gas supply port 49 into a purge space 40, and gas present in a gas suction space (grooves 61, 62, 63, and 64) is suctioned from a gas suction port 51. Atmospheric pressure in the gas suction space 30 and the gas suction space (grooves 61, 62, 63, and 64) can be controlled to be lower than atmospheric pressure in the purge space 20, atmospheric pressure in the purge space 40, and atmospheric pressure in the space outside apparatus 80.

In a case where the sample 5 is placed on the stage 11, and the defect of the sample 5 is to be detected, light 3 is emitted from the light irradiation device 1 in a state in which the atmospheric pressure in the gas suction space 30 and the gas suction space (grooves 61, 62, 63, and 64) is controlled to be lower than the atmospheric pressure in the purge space 20, the atmospheric pressure in the purge space 40, and the atmospheric pressure in the space outside apparatus 80.

The light 3 emitted from the light irradiation device 1 enters the purge space 40 from the purge space 20, enters a sample space 10 from the purge space 40, and reaches the sample 5 while passing through the plurality of optical elements 4c, 4b, and 4a. To enter the purge space 40 from the purge space 20, the light 3 passes through a sealing window 47. In addition, to enter the sample space 10 from the purge space 40, the light 3 passes through the sealing window 48. Thereafter, the light detector 6 is used to identify the positional coordinates of the defect.

Since a relatively thick metal plate is used as each of the container components 41, 42, 43, 44, 45, and 46, the container components 41, 42, 43, 44, 45, and 46 are suitable for supporting the weight of the light irradiation device 1. Meanwhile, the container components 21 and 31 are lightweight, and a relatively thin metal plate is used as each of the container components 21 and 31. For example, in a case where it is necessary to draw out the cable 2 of the light irradiation device 1, it is necessary to perform processing for forming holes 25 and 34 for the cable 2 in the container components 21 and 31. However, in a case where each of the container components 21 and 31 is a thin metal plate, such processing will be easy.

In addition, in the third embodiment, some optical elements 4c are provided in the space outside apparatus 80. However, in the fourth embodiment, such optical elements 4c can be disposed in the purge space 20. Therefore, since it is possible to reduce the possibility that contamination may adhere to the optical elements 4b and 4c, it is possible to maintain the performance of the optical elements 4b and 4c and suppress an increase in the cost of cleaning or replacing the optical elements 4b and 4c.

Regarding the position of the light irradiation device 1, any one of Modification 1, Modification 2, and Modification 3 may be used. In addition, the technique described in Modification 4 or Modification 5 may be used for the container components 41, 42, 43 and 44.

Although the present invention is described above in detail based on the embodiments described above, the present invention is not limited to the embodiments described above and can be variously modified without departing from the gist of the present invention.

### LIST OF REFERENCE SIGNS

100: optical apparatus
1: light irradiation device
1a: light source
2: cable
3: light
4a, 4b, 4c: optical element
5: sample
6: light detector
10: sample space
11: stage
12: sample container component
13: container component
13a: opening
14: sealing window
20: purge space
21: container component
22: gas supply port
23: gas supply adjustment equipment
24: ejection port
25: hole for cable
26: sealing window
30: gas suction space
31: container component
32: gas suction port
33: gas suction adjustment equipment
34: hole for cable
35: sealing window
40: purge space
41, 42, 43, 44, 45, 46: container component
47, 48: sealing window
49: gas supply port
50: gas supply adjustment equipment
51: gas suction port
52: gas suction adjustment equipment
53: ejection port
61, 62, 63, 64: groove (gas suction space)
65: through-hole
66: recessed portion
67: hole
68: through-hole
69: recessed portion
70, 71: sealing component
80: space outside apparatus

1. An optical apparatus comprising:
a light irradiation device capable of emitting light;
a plurality of container components;
a first gas supply port;
a first gas suction port; and
a first optical element, wherein
a first space to which inert gas is supplied, a second space from which gas present is suctioned, and a third space that is a space present outside the plurality of container components are separated from each other by the plurality of container components,
the first gas supply port reaches the first space,
the first gas suction port reaches the second space,
the first space is used as an optical path of the light,
the first optical element is disposed in the first space, and
atmospheric pressure in the second space can be controlled to be lower than atmospheric pressure in the first space and atmospheric pressure in the third space by supplying the inert gas from the first gas supply port into the first space and suctioning the gas present in the second space from the first gas suction port.

2. The optical apparatus according to claim 1, wherein
the light is deep ultraviolet light.

3. The optical apparatus according to claim 1, wherein
the plurality of container components include a flat plate-shaped first container component, a cover-shaped second container component, and a cover-shaped third container component,
the light irradiation device is disposed on the first container component,
the second container component is joined to the first container component,
the first space is a space surrounded by the first container component and the second container component,
the plurality of third container components are joined to the first container component so as to cover the second container component,
the second space is a space surrounded by the first container component, the second container component, and the third container component,
the first gas supply port is disposed in the second container component, and
the first gas suction port is disposed in the third container component.

4. The optical apparatus according to claim 3, further comprising:
a sample container component joined to the first container component among the plurality of container components;
a sample space surrounded by the first container component and the sample container component;
a stage that is disposed in the sample space and on which a sample can be placed;
a light detector disposed in the sample space and capable of detecting scattered light or fluorescence emitted from the sample; and
a second optical element disposed in the sample space, wherein
in a case where the sample is placed on the stage, and a defect of the sample is to be detected, the light emitted from the light irradiation device enters the sample space from the first space and reaches the sample while passing through the first optical element and the second optical element in a state in which the atmospheric pressure in the second space is controlled to be lower than the atmospheric pressure in the first space and the atmospheric pressure in the third space.

5. The optical apparatus according to claim 4, wherein,
an opening is provided in a portion of the first container component such that the first space and the sample space are the same space, and
the first space and the sample space are filled with the inert gas.

6. The optical apparatus according to claim 4, further comprising
a sealing window that is attached to a portion of the first container component and through which the light can pass, wherein
the light can enter the sample space from the first space by passing through the sealing window, and
the sample space is kept in vacuum.

7. A charged particle beam apparatus comprising:
the optical apparatus according to claim 6; and
an electron beam lens barrel disposed in the sample space and capable of emitting an electron beam, wherein
in the sample space, the stage can be moved between a position where the light reaches and a position to which the electron beam is emitted.

8. The optical apparatus according to claim 3, wherein
at least a portion of the light irradiation device is covered with the second container component such that a light source of the light irradiation device is located in the first space.

9. The optical apparatus according to claim 3, further comprising
a sealing window that is attached to a portion of the second container component and through which the light can pass, wherein
at least a portion of the light irradiation device is covered with the third container component such that a light source of the light irradiation device is located in the second space, and
the light can enter the first space from the second space by passing through the sealing window.

10. The optical apparatus according to claim 3, further comprising:
a first sealing window that is attached to a portion of the second container component and through which the light can pass; and
a second sealing window that that is attached to a portion of the third container component and through which the light can pass, wherein
the light irradiation device is disposed outside the third container component such that a light source of the light irradiation device is located in the third space, and
the light can enter the second space from the third space by passing through the second sealing window and can enter the first space from the second space by passing through the first sealing window.

11. The optical apparatus according to claim 3, wherein
the plurality of container components include:
a flat plate-shaped fourth container component facing the first container component; and
a plurality of flat plate-shaped fifth container components joined to the first container component and the fourth container component, respectively,
at least some of the plurality of fifth container components are joined to each other,
a space surrounded by the first container component, the fourth container component, and the plurality of fifth container components form a fourth space,
a groove forming a fifth space is formed along a joint surface of the first container component and the plurality of fifth container components, a joint surface of the fourth container component and the plurality of fifth container components, and a joint surface of the plurality of fifth container components one another,
the second supply port is disposed in the first container component, the fourth container component, or any one of the plurality of fifth container components so as to reach the fourth space,
the second gas suction port is disposed in the first container component, the fourth container component, or any one of the plurality of fifth container components so as to reach the groove,
the fourth space is used as a light path of the light,
the third optical element is disposed in the fourth space, and
atmospheric pressure in the fifth space can be controlled to be lower than atmospheric pressure in the fourth space and the atmospheric pressure in the third space by supplying inert gas from the second gas supply port into the fourth space and suctioning gas preset in the fifth space from the second gas suction port.

12. The optical apparatus according to claim 11, wherein
a through-hole opening the fourth space and the third space is formed in a sixth container component out of the plurality of fifth container components,
a recessed portion is formed in the sixth container component around the through-hole,
a hole is formed in a bottom of the groove of the sixth container component such that the groove and the recessed portion communicate with each other, and
a sealing component is joined to the sixth container component so as to cover the through-hole and the recessed portion.

13. The optical apparatus according to claim 11, wherein
a recessed portion is formed in a sixth container component out of the plurality of fifth container components,
a through-hole opening the fourth space and the third space is formed in a bottom of the recessed portion,
a hole is formed in a bottom of the groove of the sixth container component such that the groove and the recessed portion communicate with each other,
a first sealing component is joined to the bottom of the recessed portion so as to cover the through-hole, and
a second sealing component is joined to the sixth container component so as to cover the recessed portion.

14. The optical apparatus according to claim 11, further comprising:
a sample container component joined to the fourth container component;
a sample space surrounded by the fourth container component and the sample container component;
a stage that is disposed in the sample space and on which a sample can be placed;
a light detector disposed in the sample space and capable of detecting scattered light or fluorescence emitted from the sample; and
a second optical element disposed in the sample space, wherein
in a case where the sample is placed on the stage, and a defect of the sample is to be detected, the light emitted from the light irradiation device enters the fourth space from the first space, enters the sample space from the fourth space, and reaches the sample while passing through the first optical element, the third optical element, and the second optical element in a state in which the atmospheric pressure in the second space and the atmospheric pressure in the fifth space are controlled to be lower than the atmospheric pressure in the first space, the atmospheric pressure in the fourth space, and the atmospheric pressure in the third space.

15. A charged particle beam apparatus comprising:
the optical apparatus according to claim 14;
a first sealing window that is attached to a portion of the first container component and through which the light can pass;
a second sealing window that is attached to a portion of the fourth container component and through which the light can pass; and
an electron beam lens barrel disposed in the sample space and capable of emitting an electron beam, wherein
in a state in which the sample space is kept in vacuum, the light can enter the fourth space from the first space by passing through the first sealing window and can enter the sample space from the fourth space by passing through the second sealing window, and
in the sample space, the stage can be moved between a position where the light reaches and a position to which the electron beam is emitted.

16. The optical apparatus according to claim 1, wherein
the plurality of container components include:
a flat plate-shaped first container component;
a flat plate-shaped second container component facing the first container component; and
a plurality of flat plate-shaped third container components joined to the first container component and the second container component, respectively, wherein
at least some of the plurality of third container components are joined to each other,
the light irradiation device is disposed in the first container component,
the first space is a space surrounded by the first container component, the second container component, and the plurality of third container components,
a groove forming the second space is formed along a joint surface of the first container component and the plurality of third container components, a joint surface of the second container component and the plurality of third container components, and a joint surface of the plurality of third container components one another,
the first gas supply port is disposed in the first container component, the second container component, or any one of the plurality of third container components so as to reach the first space, and
the first gas suction port is disposed in the first container component, the second container component, or any one of the plurality of third container components so as to reach the groove.

17. The optical apparatus according to claim 16, wherein
a through-hole opening the first space and the third space is formed in a fourth container component among the plurality of third container components,
a recessed portion is formed in the fourth container component around the through-hole,
a hole is formed in a bottom of the groove of the fourth container component such that the groove and the recessed portion communicate with each other, and
a sealing component is joined to the fourth container component so as to cover the through-hole and the recessed portion.

18. The optical apparatus according to claim 16, wherein
a recessed portion is formed in a fourth container component among the plurality of third container components,
a through-hole opening the first space and the third space is formed in a bottom of the recessed portion,
a hole is formed in a bottom of the groove of the fourth container component such that the groove and the recessed portion communicate with each other,
a first sealing component is joined to the bottom of the recessed portion so as to cover the through-hole, and
a second sealing component is joined to the fourth container component so as to cover the recessed portion.

19. The optical apparatus according to claim 16, further comprising:
a sample container component joined to the second container component;
a sample space surrounded by the second container component and the sample container component;
a stage that is disposed in the sample space and on which a sample can be placed;
a light detector disposed in the sample space and capable of detecting scattered light or fluorescence emitted from the sample; and
a second optical element disposed in the sample space, wherein
in a case where the sample is placed on the stage, and a defect of the sample is to be detected, the light emitted from the light irradiation device enters the sample space from the first space and reaches the sample while passing through the first optical element and the second optical element in a state in which the atmospheric pressure in the second space is controlled to be lower than the atmospheric pressure in the first space and the atmospheric pressure in the third space.

20. A charged particle beam apparatus comprising:
the optical apparatus according to claim 19;
a first sealing window that is attached to a portion of the first container component and through which the light can pass;
a second sealing window that is attached to a portion of the second container component and through which the light can pass; and
an electron beam lens barrel disposed in the sample space and capable of emitting an electron beam, wherein
the light can enter the first space from the third space by passing through the first sealing window and can enter the sample space from the first space by passing through the second sealing window in a state in which the sample space is kept in vacuum, and
in the sample space, the stage can be moved between a position where the light reaches and a position to which the electron beam is emitted.
